(19) United States
(12) Patent Application Publication
(10) Pub. No.: US 2026/0223376 A1
(43) Pub. Date: Jul. 30, 2026

(54) SEMICONDUCTOR DEVICES HAVING CONDUCTIVE CONNECTION LINES

(71) Applicant: Samsung Electronics Co., Ltd., Suwon-si (KR)

(72) Inventors: Yujin Kim, Suwon-si (KR); Jinwoo Han, Suwon-si (KR); Juhyun Kim, Suwon-si (KR); Hyeoncheol Kim, Suwon-si (KR)

(21) Appl. No.: 19/456,204

(22) Filed: Jan. 22, 2026

(30) Foreign Application Priority Data
Jan. 24, 2025 (KR) 10-2025-0011025

(51) Int. Cl. H10B 80/00; G11C 11/4091; H10B 12/00; H10W 90/00; H10W 90/20

(52) U.S. Cl. CPC H10B 80/00; G11C 11/4091; H10B 12/30; H10B 12/50; H10W 90/20; H10W 90/792

(57) ABSTRACT

A semiconductor device includes a cell array substrate and a peripheral circuit substrate on the cell array substrate. The cell array substrate includes a memory cell region and a pad region, active patterns extending in a first horizontal direction on the memory cell region and spaced apart from each other in a vertical direction, bit lines contacting the active patterns and extending in the vertical direction, gate electrodes extending in a second horizontal direction, conductive connection lines electrically connected to the bit lines, and pad portions connected to the gate electrodes and on the pad region. The memory cell region includes a first sub-cell region, a second sub-cell region and a third sub-cell region sequentially arranged in the first horizontal direction. The bit lines include a first bit line, a second bit line, a third bit line, and a fourth bit line.

### CROSS-REFERENCE TO RELATED APPLICATION(S)

This application claims the benefit under 35 USC 119(a) of Korean Patent Application No. 10-2025-0011025 filed on January 24, 2025 in the Korean Intellectual Property Office, the entire disclosure of which is incorporated herein by reference for all purposes.

### BACKGROUND

The present application relates to semiconductor devices having conductive connection lines.

As demand for high performance, high speed, and/or multifunctionality of semiconductor devices increases, the integration of semiconductor devices is increasing. In manufacturing semiconductor devices with fine patterns corresponding to the trend for high integration of semiconductor devices, patterns having fine widths or fine spacings may be implemented.

### SUMMARY

Example embodiments provide a semiconductor device having a conductive connection line.

According to example embodiments, a semiconductor device comprises a cell array substrate; and a peripheral circuit substrate on the cell array substrate, wherein the cell array substrate includes, a memory cell region and a pad region adjacent to the memory cell region; active patterns extending in a first horizontal direction on the memory cell region and spaced apart from each other in a vertical direction; bit lines contacting the active patterns and extending in the vertical direction; gate electrodes extending in a second horizontal direction that crosses the first horizontal direction, the gate electrodes intersecting the active patterns on the memory cell region; conductive connection lines electrically connected to the bit lines, the conductive connection lines being on the memory cell region and extending in the first horizontal direction; and pad portions connected to the gate electrodes and on the pad region, wherein the memory cell region includes a first sub-cell region, a second sub-cell region and a third sub-cell region sequentially arranged in that order in the first horizontal direction, the bit lines include, a first bit line on the first sub-cell region; a second bit line adjacent to the first bit line, on the second sub-cell region; a third bit line spaced apart from the second bit line, on the second sub-cell region; and a fourth bit line adjacent to the third bit line, on the third sub-cell region, and the conductive connection lines include, a first conductive connection line electrically connecting the first bit line and the third bit line, on the second sub-cell region; and a second conductive connection line electrically connecting the second bit line and the fourth bit line, on the second sub-cell region.

According to example embodiments, a semiconductor device comprises a cell array substrate; and a peripheral circuit substrate on the cell array substrate, wherein the cell array substrate includes, a memory cell region and a pad region adjacent to the memory cell region; stack structures arranged in a first horizontal direction on the memory cell region; conductive connection lines extending in the first horizontal direction on the stack structures and spaced apart from each other in a second horizontal direction that crosses the first horizontal direction; and pad structures connected to the stack structures and on the pad region, each of the stack structures includes, active patterns extending in the first horizontal direction; bit lines extending in a vertical direction and contacting the active patterns; and gate electrodes extending in the second horizontal direction and intersecting the active patterns, and wherein the conductive connection lines are electrically connected to the bit lines and vertically overlap two adjacent gate electrodes among the gate electrodes.

According to example embodiments, a semiconductor device comprises a cell array substrate; and a peripheral circuit substrate on the cell array substrate, wherein the cell array substrate includes, a memory cell region and a pad region adjacent to the memory cell region; stack structures arranged in a first horizontal direction on the memory cell region; conductive connection lines extending in the first horizontal direction on the stack structures and spaced apart from each other in a second horizontal direction that crosses the first horizontal direction; and pad structures connected to the stack structures and on the pad region, each of the stack structures includes, active patterns extending in the first horizontal direction; bit lines extending in a vertical direction and contacting first side surfaces of the active patterns; a data storage structure contacting second side surfaces of the active patterns, opposite to the first side surfaces; and gate electrodes extending in the second horizontal direction, the gate electrodes surrounding the active patterns, and wherein the pad structures include pad portions spaced apart from each other in the vertical direction and connected to the gate electrodes, wherein the conductive connection lines are electrically connected to the bit lines and vertically overlap two adjacent gate electrodes among the gate electrodes, and wherein ends of the conductive connection lines are disposed in a zigzag manner along the second horizontal direction.

### BRIEF DESCRIPTION OF DRAWINGS

The above and other aspects, features, and advantages of the present application will be more clearly understood from the following detailed description, taken in conjunction with the accompanying drawings, in which:

FIG. 1 is a perspective view schematically illustrating a semiconductor device according to example embodiments;

FIG. 2 is a schematic circuit diagram of a semiconductor device according to an example embodiment;

FIG. 3 is a schematic perspective view of a cell array substrate of a semiconductor device according to an example embodiment;

FIG. 4 is a plan view of a cell array substrate of a semiconductor device according to an example embodiment;

FIG. 5 is a vertical cross-sectional view along line I-I’ of the semiconductor device illustrated in FIG. 4;

FIG. 6 is an enlarged view of a portion of FIG. 4;

FIG. 7 is a vertical cross-sectional view along line II-II’ of the semiconductor device illustrated in FIG. 6;

FIG. 8 is a schematic perspective view of bit lines and conductive connection lines according to an example embodiment;

FIG. 9 is a vertical cross-sectional view of a semiconductor device according to an example embodiment;

FIG. 10 is a schematic perspective view of a cell array substrate of a semiconductor device according to an example embodiment; and

FIGS. 11 to 13 are plan views of cell array substrates of semiconductor devices according to example embodiments.

### DETAILED DESCRIPTION

Hereinafter, example embodiments will be described with reference to the accompanying drawings.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

As used herein, components described as being “electrically connected” are configured such that an electrical signal can be transferred from one component to the other (although such electrical signal may be attenuated in strength as it is transferred and may be selectively transferred).

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

It will be understood that when an element is referred to as being "connected" or "coupled" to or “on” another element, it can be directly connected or coupled to or on the other element or intervening elements may be present. In contrast, when an element is referred to as being "directly connected," "directly attached," "directly joined," or "directly coupled" to another element, or as “contacting” or “in contact with” another element (or using any form of the word “contact”), there are no intervening elements present at the point of contact. Further, in the specification, the word “on” may refer to positioning above, to the side or below an object, and does not necessarily mean positioned on the upper side of the object.

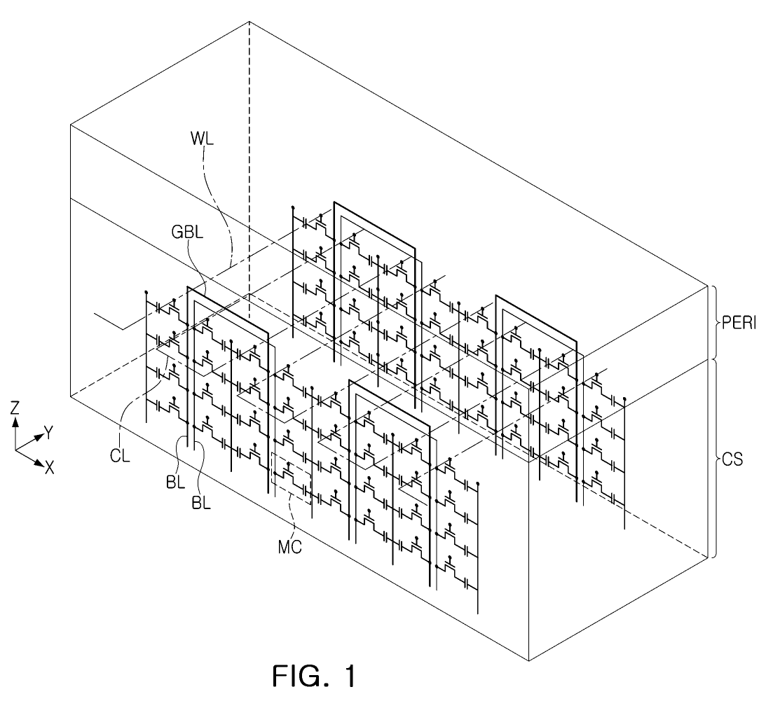

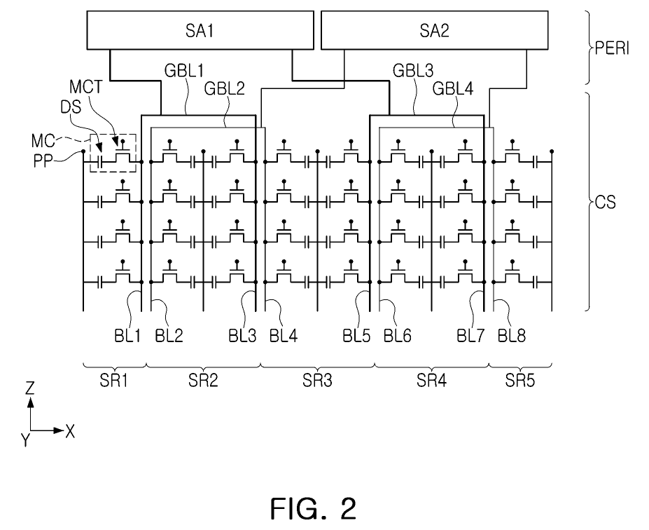

FIG. 1 is a perspective view schematically illustrating a semiconductor device according to example embodiments. FIG. 2 is a schematic circuit diagram of a semiconductor device according to example embodiments.

Referring to FIGS. 1 and 2, a semiconductor device 100 according to example embodiments may include a cell array substrate CS and a peripheral circuit substrate PERI that is in contact with and connected to the cell array substrate CS. The peripheral circuit substrate PERI may overlap the cell array substrate CS in a vertical direction. Each of the cell array substrate CS and the peripheral circuit substrate CS may be a portion of a corresponding semiconductor wafer.

The cell array substrate CS may include a plurality of sub-cell arrays SCA. The plurality of sub-cell arrays SCA may be arranged in the Y-direction. Each of the plurality of sub-cell arrays SCA may include a plurality of bit lines BL, a plurality of word lines WL, a plurality of connection lines CL, a plurality of memory cells MC, and a plurality of plate electrodes PP. The memory cell MC may include a memory cell transistor MCT and a data storage element DS. A memory cell MC may be disposed between one word line WL and one bit line BL. The cell array of the semiconductor device may correspond to the memory cell array of a Dynamic Random Access Memory (DRAM) element.

The word lines WL may extend in the Y-direction. For convenience of explanation, a single layer of word lines WL is illustrated in FIG. 1, but the word lines WL may form multiple layers, and for example, may be spaced apart from each other in the X-direction and the Z-direction.

The connection lines CL may be spaced apart from each other in the Z-direction and may connect word lines WL disposed at the same level. For example, the connection lines CL may connect two word lines WL adjacent in the X-direction.

The bit lines BL may extend in the Z-direction and may be spaced apart from each other in the X-direction.

A memory cell transistor MCT may include a gate, a source, and a drain. The gate may be connected to a word line WL, the source may be connected to a bit line BL, and the drain may be connected to a data storage element DS. The data storage element DS may include a capacitor formed of lower and upper electrodes and a dielectric layer.

The plate electrodes PP may extend in the Z-direction and be electrically connected to the data storage elements DS. The plate electrodes PP may be disposed between memory cells MC adjacent to each other in the X-direction, respectively.

Referring further to FIG. 2, the memory cell region of the cell array substrate CS may include first to fifth sub-cell regions SR1, SR2 and SR3, SR4 and SR5. The bit lines BL may include first to eighth bit lines BL1, BL2, BL3, BL4, BL5, BL6, BL7, and BL8. The first bit line BL1 may be disposed on the first sub-cell region SR1. The second and third bit lines BL2 and BL3 may be disposed on the second sub-cell region SR2. The fourth and fifth bit lines BL4 and BL5 may be disposed on the third sub-cell region SR3. The sixth and seventh bit lines BL6 and BL7 may be disposed on the fourth sub-cell region SR4. The eighth bit line BL8 may be disposed on the fifth sub-cell region SR5. The first to fifth sub-cell regions SR1, SR2 and SR3, SR4 and SR5 may be sequentially arranged such that the second sub-cell region SR2 is immediately adjacent to, and between, the first sub-cell region SR1 and the third sub-cell region SR3, the third sub-cell region SR3 is immediately adjacent to, and between, the second sub-cell region SR2 and the fourth sub-cell region SR4, and the fourth sub-cell region SR4 is immediately adjacent to, and between, the third sub-cell region SR3 and the fifth sub-cell region SR5.

The cell array substrate CS may further include global bit lines GBL1, GBL2, GBL3 and GBL4 connecting the bit lines BL. The first global bit line GBL1 may connect the first bit line BL1 and the third bit line BL3. The second global bit line GBL2 may connect the second bit line BL2 and the fourth bit line BL4. The third global bit line GBL3 may connect the fifth bit line BL5 and the seventh bit line BL7. The fourth global bit line GBL4 may connect the sixth bit line BL6 and the eighth bit line BL8.

The peripheral circuit substrate PERI may include bit line sense amplifiers SA1 and SA2. The first bit line sense amplifier SA1 may be connected to the first global bit line GBL1 and the third global bit line GBL3. The second bit line sense amplifier SA2 may be connected to the second global bit line GBL2 and the fourth global bit line GBL4.

According to embodiments, each of the global bit lines GBL1, GBL2, GBL3 and GBL4 connects two bit lines BL between the bit line sense amplifiers SA1 and SA2 and the bit lines BL, so that the number of bit line sense amplifiers SA1 and SA2 may be reduced compared to the case where the bit lines BL are directly connected to the bit line sense amplifiers SA1 and SA2. For example, the size of the area where the bit line sense amplifiers SA1 and SA2 are formed within the peripheral circuit substrate PERI may be increased. As illustrated in FIG. 2, in embodiments, the first bit line sense amplifier SA1 may comprise a length in the X-direction that is large enough to overlap a plurality of the sub-cell regions, for example, with the first bit line sense amplifier SA1 overlapping the first sub-cell region SR1, the second sub-cell region SR2, and at least a portion of the third sub-cell region SR3. Likewise, in embodiments, the second bit line sense amplifier SA2 may comprise a length in the X-direction that is large enough to overlap a plurality of the sub-cell regions, for example, with the second bit line sense amplifier SA2 overlapping the fourth sub-cell region SR4, the fifth sub-cell region SR5, and at least a portion of the third sub-cell region SR3.

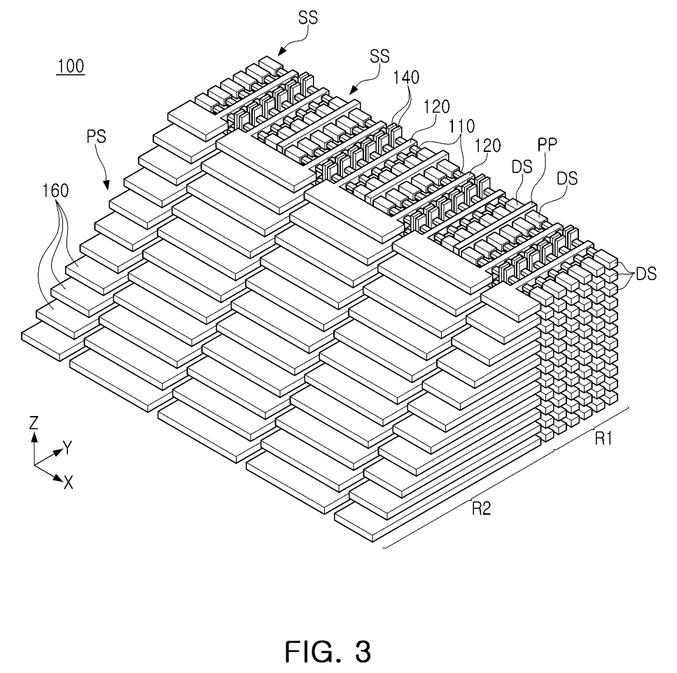

According to an example embodiment, the circuit diagrams of FIGS. 1 and 2 may be implemented with, for example, semiconductor devices described in FIGS. 3 to 13 below.

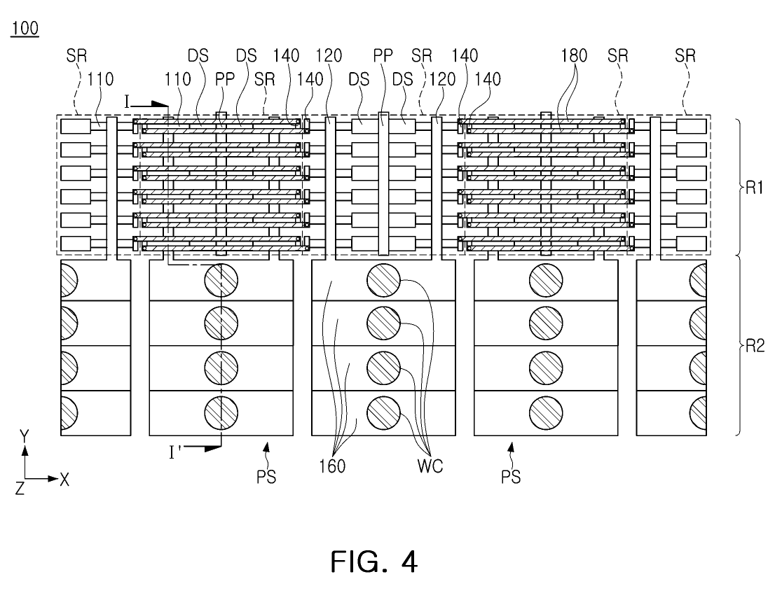

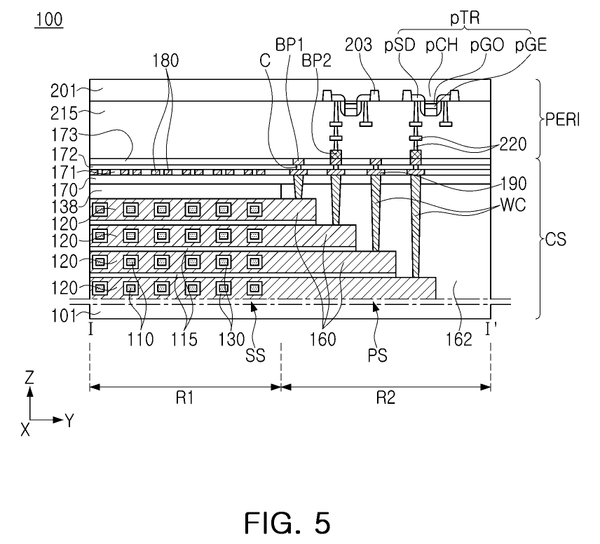

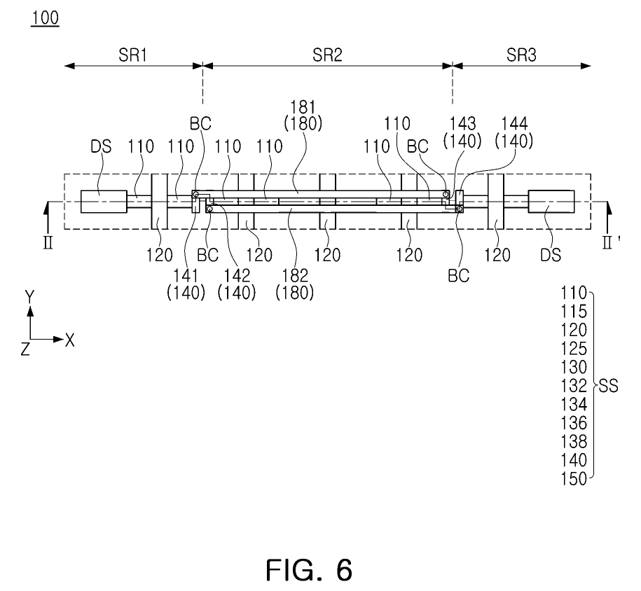

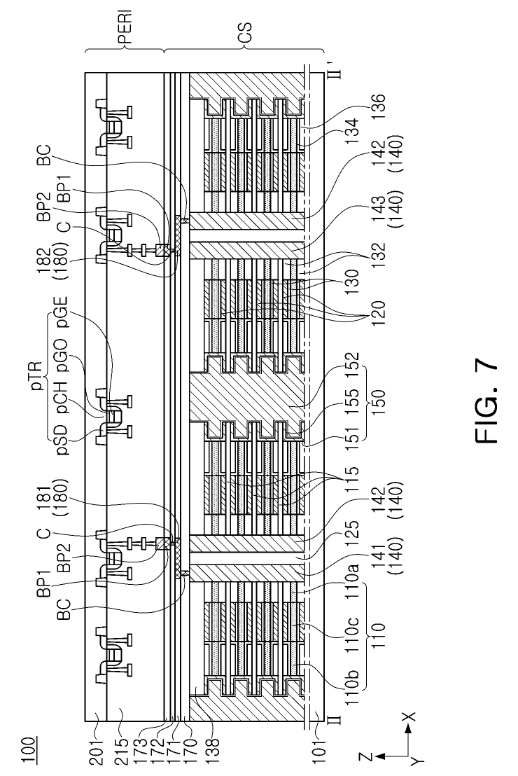

FIG. 3 is a schematic perspective view of a cell array substrate of a semiconductor device according to an example embodiment. FIG. 4 is a plan view of a cell array substrate of a semiconductor device according to an example embodiment. FIG. 5 is a vertical cross-sectional view along line I-I’ of the semiconductor device illustrated in FIG. 4. FIG. 6 is an enlarged view of a portion of FIG. 4. FIG. 7 is a vertical cross-sectional view along line II-II’ of the semiconductor device illustrated in FIG. 6.

Referring to FIGS. 3 to 7, the semiconductor device 100 may include a cell array substrate CS and a peripheral circuit substrate PERI that is in contact with and connected to the cell array substrate CS. The peripheral circuit substrate PERI may overlap the cell array substrate CS in a vertical direction.

The substrate 101 of the cell array substrate CS may include a memory cell region R1 and a pad region R2. The cell array substrate CS of the semiconductor device 100 may include active patterns 110, gate electrodes 120, bit lines 140, and a data storage structure 150 disposed on a substrate 101 on a memory cell region R1. The semiconductor device 100 may also include pad portions 160 disposed on a pad region R2.

The semiconductor device 100 may include, for example, a cell array of DRAM memory cells. The bit lines 140 may correspond to the bit lines BL of FIGS. 1 and 2, at least one of the gate electrodes 120 may correspond to the word line WL of FIGS. 1 and 2, and the data storage structure 150 may correspond to the data storage element DS and the plate electrode PP of FIG. 2.

The substrate 101 may be or include a crystalline semiconductor substrate and constitute an initial substrate (or base substrate) on which additional layers are formed (e.g. to form cell array substrate CS). Substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may further include impurities. The substrate 101 may be a bulk silicon substrate, a silicon-on-insulator (SOI) substrate, a bulk germanium substrate, a germanium-on-insulator (GOI) substrate, a bulk silicon-germanium substrate, or a substrate including an epitaxial layer.

The active patterns 110 are disposed on the substrate 101 and may extend horizontally in the X-direction. The active patterns 110 may be spaced apart from each other in the Y-direction and the Z-direction. In the plan view of FIG. 4, the active patterns 110 may extend linearly and may have a line shape, a bar shape, or a pillar shape extending in the X-direction intersecting the gate electrodes 120. In one example, the active patterns 110 may include a semiconductor material, for example, silicon, germanium, or silicon-germanium.

Each of the active patterns 110 may include a first impurity region 110a, a second impurity region 110b, and a channel region 110c. The channel region 110c may be positioned between the first impurity region 110a and the second impurity region 110b. The first impurity region 110a may be in contact with a bit line 140 and electrically connected to the bit line 140. The second impurity region 110b may be in contact with a first electrode 151 of the data storage structure 150 and electrically connected to the first electrode 151. The length of the first impurity region 110a in the X-direction and the length of the second impurity region 110b in the X-direction may be different from each other or may be the same. The channel region 110c may overlap the gate electrodes 120 in the Z-direction. When the active pattern 110 is formed of a semiconductor material, the first impurity region 110a and the second impurity region 110b may each include impurities, and the impurities may have an n-type or p-type conductivity.

At least a part of the first impurity region 110a may correspond to the first source/drain region of the memory cell transistor MCT of FIG. 1, and at least a part of the second impurity region 110b may correspond to the second source/drain region of the memory cell transistor MCT of FIG. 1. At least a part of the channel region 110c may correspond to the channel of the memory cell transistor MCT of FIG. 1. The first impurity region 110a may provide a region for directly connecting the memory cell transistor MCT to the bit line BL, and the second impurity region 110b may provide a region for directly connecting the memory cell transistor MCT to the data storage element DS.

In another example, the active patterns 110 may be formed of at least one of an oxide semiconductor, for example, hafnium-silicon oxide (HSO), hafnium-zinc oxide (HZO), indium-zinc oxide (IZO), indium-gallium oxide (IGO), indium-tin oxide (ITO), indium-gallium-zinc oxide (IGZO), and indium-tin-zinc oxide (ITZO).

In another example, the active patterns 110 may be a two-dimensional material (2D material) in which atoms form a predetermined crystal structure and may form a channel of the transistor. The two-dimensional material layer may include at least one of a transition metal dichalcogenide (TMD) material layer, a black phosphorous material layer, and a hexagonal boron-nitride material layer. For example, the two-dimensional material layer may be formed of at least one of BiOSe, Crl, WSe2, MoS2, TaS, WS, SnSe, ReS, β-SnTe, MnO, AsS, P(black), InSe, h-BN, GaSe, GaN, SrTiO, MXene, and Janus 2D materials, forming a two-dimensional material.

In some embodiments, the semiconductor device 100 may further include epitaxial layers grown from the active pattern 110 and connected to the first impurity region 110a and the second impurity region 110b of the active pattern 110, respectively.

The gate electrodes 120 are disposed on the substrate 101 and may extend horizontally in the Y-direction. The gate electrodes 120 may be disposed to be spaced apart from each other in the X-direction and the Z-direction. The gate electrodes 120 may be disposed between the channel regions 110c of the active pattern 110. In a plan view, the gate electrodes 120 may extend linearly and may have a line shape, a bar shape, or a pillar shape that intersects the active pattern 110 or extends in the Y-direction while crossing the active pattern 110.

The gate electrodes 120 may include a conductive material, and the conductive material may include at least one of a doped semiconductor material (for example, doped silicon, doped germanium, or the like), a conductive metal nitride (for example, titanium nitride, tantalum nitride, tungsten nitride, or the like), a metal (for example, tungsten, titanium, tantalum, cobalt, aluminum, ruthenium, or the like), and a metal-semiconductor compound (for example, tungsten silicide, cobalt silicide, titanium silicide, or the like). At least one of the gate electrodes 120 may correspond to the word lines WL described with reference to FIGS. 1 and 2.

In an example embodiment, the gate electrodes 120 may be disposed in a gate all around structure surrounding the active pattern 110. In an example embodiment, the gate electrodes 120 may be disposed in a double gate structure. For example, gate electrodes 120 may be disposed on the upper surface and lower surface of respective active patterns 110, and two gate electrodes 120 adjacent to each active pattern 110 may form one word line WL. In an example embodiment, the gate electrodes 120 may be disposed in a single gate structure. For example, one of the gate electrodes 120 may be disposed adjacent to each active pattern 110, and one gate electrode 120 may form one word line WL.

The cell array substrate CS of the semiconductor device 100 may further include a gate dielectric layer 130, a spacer 132, a first capping pattern 134, and a second capping pattern 136. In an example embodiment, the gate electrode 120 may be disposed in a Gate All Around structure surrounding the active pattern 110, and the gate dielectric layer 130 may be disposed to surround the active pattern 110 between the active pattern 110 and the gate electrode 120. In an example embodiment, the gate electrodes 120 may be disposed in a double gate structure, and the gate dielectric layers 130 may cover the upper surface and the lower surface of respective active patterns 110. In an example embodiment, the gate electrodes 120 may be disposed in a single gate structure, and the gate dielectric layers 130 may cover one of the upper surface and the lower surface of respective active patterns 110.

The gate dielectric layer 130 may be formed of at least one of silicon oxide, silicon nitride, a low-κ material, and a high-κ material. The high-κ dielectric material may comprise a dielectric material having a higher dielectric constant than silicon oxide, and the low-κ dielectric material may comprise a dielectric material having a lower dielectric constant than silicon oxide. The high-κ dielectric material may be, for example, a metal oxide or a metal oxynitride. The high-κ dielectric material may be, for example, any one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSixOy), hafnium oxide (HfO₂), hafnium silicon oxide (HfSixOy), lanthanum oxide (La₂O₃), lanthanum aluminum oxide (LaAlxOy), lanthanum hafnium oxide (LaHfxOy), hafnium aluminum oxide (HfAlxOy), and praseodymium oxide (Pr₂O₃). The gate dielectric layer 130 may be formed as a single layer or multiple layers of the aforementioned materials.

The spacer 132 may be disposed between the gate electrode 120 and the bit line 140. The spacer 132 may overlap with the first impurity region 110a of the active pattern 110 in a vertical direction. The spacer 132 may be formed of at least one of silicon nitride, silicon oxynitride, and silicon oxycarbide. For example, the spacer 132 may be formed of silicon nitride.

The first capping pattern 134 and the second capping pattern 136 may be disposed between the gate electrode 120 and the data storage structure 150. The first capping pattern 134 and the second capping pattern 136 may overlap with the second impurity region 110b of the active pattern 110 in a vertical direction. The first capping pattern 134 may be in contact with the second impurity region 110b of the active pattern 110, the gate electrode 120, and the gate dielectric layer 130. The second capping pattern 136 may be disposed on the first capping pattern 134. The first capping pattern 134 and the second capping pattern 136 may be formed of at least one of silicon nitride, silicon oxynitride, and silicon oxycarbide.

The cell array substrate CS of the semiconductor device 100 may further include an interlayer insulating layer 115. The interlayer insulating layer 115 may be disposed between vertically adjacent active patterns 110 and between vertically adjacent gate electrodes 120. The interlayer insulating layers 115 may extend in the horizontal direction and may be vertically spaced apart from each other. One end of the interlayer insulating layer 115 may be in contact with a side surface of a bit line 140, and the other end opposite to the one end may be disposed between first electrodes 151 of a data storage structure 150. The upper surface and the lower surface of the interlayer insulating layer 115 may be in contact with the gate electrode 120, the spacer 132, the first capping pattern 134, and the second capping pattern 136. The interlayer insulating layer 115 may electrically insulate adjacent gate electrodes 120 from each other.

The interlayer insulating layer 115 may be formed of at least one of silicon oxide, silicon nitride, silicon oxynitride, and silicon oxycarbide. For example, the interlayer insulating layer 115 may be formed of silicon oxide.

The bit lines 140 may extend vertically in the Z-direction on the substrate 101. The bit lines 140 may be disposed to be spaced apart from each other in the X-direction and the Y-direction. A plurality of active patterns 110 stacked in the Z-direction on one bit line 140 may be electrically connected. For example, the bit line 140 may be electrically connected to the first impurity regions 110a. The bit lines 140 may extend linearly and may have a line shape, a bar shape, or a pillar shape extending in the Z-direction. The bit lines 140 may be formed of at least one of a doped semiconductor material, a conductive metal nitride, a metal, and a metal-semiconductor compound. The bit lines 140 may correspond to the bit lines BL described with reference to FIG. 1.

The cell array substrate CS of the semiconductor device 100 may further include a vertical insulating pillar 125. The vertical insulating pillar 125 may be disposed between adjacent bit lines 140 in the X-direction. The vertical insulating pillars 125 may extend in the vertical direction and may be spaced apart from each other in the X-direction. The vertical insulating pillar 125 may electrically insulate the adjacent bit lines 140 from each other.

The vertical insulating pillar 125 may be formed of at least one of silicon oxide, silicon nitride, silicon oxynitride, and silicon oxycarbide. For example, the vertical insulating pillar 125 may be formed of silicon oxide.

The data storage structure 150 may include a first electrode 151, a second electrode 152, and a capacitor dielectric 155 between the first and second electrodes 151, 162. The data storage structure 150 may form a plurality of data storage elements DS and plate electrodes PP connected to the plurality of data storage elements DS. For example, the first electrode 151 and the second electrode 152 (e.g., wherein the second electrode 152 vertically overlaps the first electrode 151 and a portion of the capacitor dielectric 155) may be referred to as a data storage element DS. The plate electrode PP may extend in the Z-direction and may be electrically connected to the data storage elements DS. For example, the plate electrode PP may be composed of the second electrode 152.

The data storage structure 150 may be in contact with a second impurity region 110b of the active pattern 110. The data storage structure 150 may be electrically connected to the second impurity region 110b of the active pattern 110. The first electrode 151 may have a cylinder shape, but is not limited thereto, and may have a pillar shape according to an example embodiment.

The first electrodes 151 may be in a node-separated state, and for example, the first electrodes 151 may be electrically insulated from each other by an interlayer insulating layer 115. The first electrodes 151 may be referred to as ‘storage node electrodes’. The first electrodes 151 may be formed of at least one of a doped semiconductor material, a conductive metal nitride, a metal, and a metal-semiconductor compound.

The capacitor dielectric 155 may conformally cover the first electrode 151. The capacitor dielectric 155 may be formed of one or more high-κ materials, such as zirconium oxide (ZrO₂), aluminum oxide (Al₂O₃), and hafnium oxide (Hf₂O₃), for example.

The second electrode 152 may cover the capacitor dielectric 155 and may extend in the X-direction. At least a portion of the second electrode 152 may be referred to as a plate electrode PP. The second electrode 152 may be formed of at least one of a doped semiconductor material, a conductive metal nitride, a metal, and a metal-semiconductor compound.

The cell array substrate CS of the semiconductor device 100 may further include an insulating layer 138. The insulating layer 138 may be disposed on an uppermost gate electrode 120 among the gate electrodes 120 and may be in contact with the bit line 140 and side surfaces of the data storage structure 150. The insulating layers 138 may extend in the X-direction and may be spaced apart from each other in the X-direction. The insulating layers 138 may be coplanar with the upper surface of the bit lines 140.

The insulating layer 138 may be formed of at least one of silicon oxide, silicon nitride, silicon oxynitride, and silicon oxycarbide. For example, the insulating layer 138 may be formed of silicon oxide.

The pad portions 160 may be disposed on the substrate 101 and may be connected to the gate electrodes 120. For example, the pad portions 160 may be in contact with the ends of the gate electrodes 120, and at least a portion of the pad portions 160 may extend in the X-direction. The pad portions 160 may be disposed spaced apart from each other in the vertical direction. In a plan view, the pad portions 160 may have a line shape, a bar shape, or a pillar shape extending in the X-direction. The pad portions 160 may correspond to the connecting lines CL described with reference to FIG. 1.

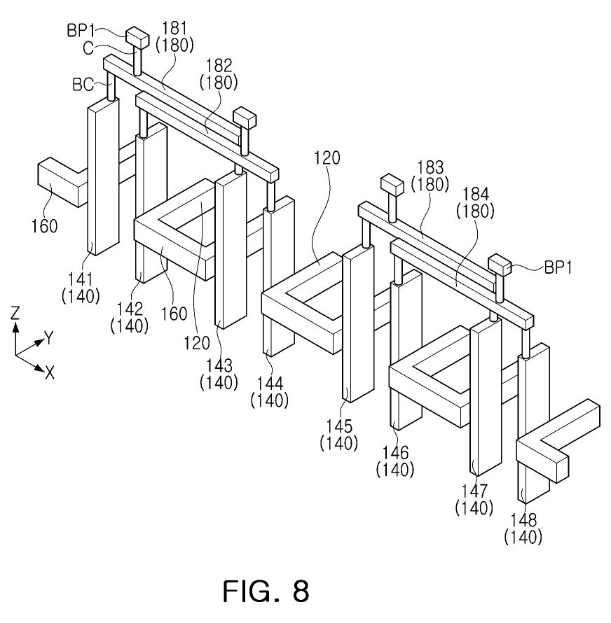

The pad portions 160 may electrically connect the gate electrodes 120 disposed at the same level. For example, each pad portion 160 may electrically connect two gate electrodes 120 disposed at the same level and adjacent in the X-direction. The pad portions 160 may include the same material as the gate electrodes 120. In some embodiments, the pad portions 160 may be formed integrally with the gate electrodes 120. As illustrated in FIGS. 4 and 8, in embodiments, each pad portion 160 may be connected to two gate electrodes 120, with the two gate electrodes 120 spaced apart from each other, and extending parallel to each other, while being connected to a respective pad portion 160.

The cell array substrate CS may include a stack structure SS disposed on the memory cell region R1. Components disposed on the substrate 101 on the memory cell region R1 may form the stack structure SS. For example, the stack structure SS may include active patterns 110, interlayer insulating layers 115, gate electrodes 120, vertical insulating pillars 125, gate dielectric layers 130, spacers 132, first capping patterns 134, second capping patterns 136, insulating layers 138, bit lines 140, and data storage structures 150. The memory cell region R1 may include sub-cell regions SR disposed in the X-direction, and the stack structure SS may be disposed on the respective sub-cell regions SR. The sub-cell regions SR may be defined as regions adjacent to the pad structure PS in the Y-direction. The stack structure SS may include two gate electrodes 120 that are adjacent in the X-direction and intersect with the active patterns 110, a data storage structures DS and PP between the two gate electrodes 120, and bit lines 140 that are connected to the ends of the active patterns 110.

The cell array substrate CS may include a pad structure PS that is disposed on a pad region R2. Components disposed on the substrate 101 on the pad region R2 may form the pad structure PS. For example, pad portions 160 that are spaced apart from each other in the vertical direction may form the pad structure PS. The pad structure PS may be electrically connected to the stack structure SS. As described above, each of the pad portions 160 of the pad structure PS may be in contact with two gate electrodes 120 of the stack structure SS. In an example embodiment, the pad structure PS may have a step structure, for example, with the pad portions 160 arranged in a step structure. For example, as illustrated in FIG. 5, the horizontal width along the Y-direction of the pad portion 160 that is relatively lower than an overlapping pad portion 160 (e.g., that is vertically above the overlapped pad portion 160) may be relatively larger than the overlapping pad portion 160. Accordingly, among two pad portions 160 (e.g., a lower pad portion and an upper pad portion) that are vertically adjacent to each other, the lower pad portion may have a horizontal width along the Y-direction that is greater than a horizontal width along the Y-direction of the upper pad portion. The pad structure PS may decrease in height in the -Y-direction opposite to the Y-direction.

The cell array substrate CS of the semiconductor device 100 may further include an insulating layer 162, a first upper insulating layer 170, a second upper insulating layer 171, a third upper insulating layer 172, and a fourth upper insulating layer 173 on the stack structure SS and the pad structure PS. The insulating layer 162 may cover the pad structure PS and may be coplanar with the upper surface of the insulating layer 138. The first upper insulating layer 170, the second upper insulating layer 171, the third upper insulating layer 172, and the fourth upper insulating layer 173 may be sequentially stacked on the insulating layer 138 and the insulating layer 162.

The insulating layer 162, the first upper insulating layer 170, the second upper insulating layer 171, the third upper insulating layer 172, and the fourth upper insulating layer 173 may be formed of at least one of silicon oxide, silicon nitride, silicon oxynitride, and silicon oxycarbide.

The cell array substrate CS of the semiconductor device 100 may further include word line contacts WC on the pad structure PS. The word line contacts WC may vertically penetrate the insulating layer 162 and the first upper insulating layer 170 and be connected to pad portions 160 of the pad structure PS. In an example embodiment, the pad structure PS has a step structure, and the word line contacts WC may be in contact with the upper surface of the corresponding pad portion 160. In an example embodiment, the pad portions 160 of the pad structure PS may have the same horizontal width, and the word line contacts WC may vertically penetrate one or more pad portions 160 and be in contact with the upper surface of the corresponding pad portion 160. The upper surfaces of the word line contacts WC may be coplanar with the upper surface of the first upper insulating layer 170.

The cell array substrate CS of the semiconductor device 100 may further include conductive connection lines 180 and bit line contacts BC on the stack structure SS. The conductive connection lines 180 may be disposed at the same level as the second upper insulating layer 171. The bit line contacts BC may vertically penetrate the first upper insulating layer 170 and may be in contact with the bit line 140 and the conductive connection line 180. In the plan view, at least some of the conductive connection lines 180 adjacent in the Y-direction may not overlap in the Y-direction. For example, the conductive connection lines 180 adjacent in the Y-direction may be disposed to be offset in the X-direction, and ends of the conductive connection lines 180 may be disposed in a zigzag manner along the Y-direction. For example, with reference to FIGS. 6 and 8, the conductive connection lines 180 may comprise a first conductive connection line 181 and a second conductive connection line 182 that extend parallel to each other and may be located at the same level relative to the Z-direction. By being disposed in the zigzag manner, the first conductive connection line 181 and the second conductive connection line 182 may be offset relative to each other along the X-direction. For example, a first axis that extends in the Y-direction (e.g., in a direction perpendicular to the first conductive connection line 181 and the second conductive connection line 182) may intersect the first conductive connection line 181 (e.g., an end of the first conductive connection line 181) while not intersecting the second conductive connection line 182. Similarly, a second axis that extends in the Y-direction (e.g., parallel to the first axis and in a direction perpendicular to the first conductive connection line 181 and the second conductive connection line 182) may intersect the second conductive connection line 182 (e.g., an end of the second conductive connection line 182) while not intersecting the first conductive connection line 181. In embodiments, a third axis that extends in the Y-direction (e.g., parallel to the first axis and second axis and located between the first axis and the second axis) may intersect the first conductive connection line 181 (e.g., a central region of the first conductive connection line 181) and the second conductive connection line 182 (e.g., a central region of the second conductive connection line 182). The first axis, the second axis, and the third axis may extend in a direction that is perpendicular to the X-direction and the Z-direction. The conductive connection line 180 may comprise other connection lines (e.g., 183, 184, etc.) that may be arranged in a similar manner as the first conductive connection line 181 and the second conductive connection line 182. The conductive connection line 180 may extend in the X-direction and may vertically overlap two gate electrodes 120 adjacent in the X-direction among the gate electrodes 120. The bit lines 140 may be referred to as ‘local bit lines’, and the conductive connection lines 180 may be referred to as ‘global bit lines’.

FIG. 8 is a schematic perspective view of bit lines and conductive lines according to an example embodiment. FIG. 8 is a drawing for explaining an electrical connection relationship of the circuit diagram illustrated in FIG. 2.

Referring to FIGS. 4, 6, and 8, conductive connection lines 180 may extend in the X-direction on the stack structure SS and may be spaced apart from each other in the Y-direction and, in addition or in the alternative, may be spaced apart from each other in the X-direction. For example, the first conductive connection line 181 and the third conductive connection line 183 may be spaced apart from each other in the X-direction while not being spaced apart from each other in the Y-direction. As such, the first conductive connection line 181 and the third conductive connection line 183 may lie within the same axis (e.g., an axis extending in the X-direction may pass through the first conductive connection line 181 and the third conductive connection line 183) and may be collinear while being spaced apart in the X-direction. The first conductive connection line 181 and the fourth conductive connection line 184 may be spaced apart from each other in the X-direction and may be spaced apart from each other in the Y-direction. As such, the first conductive connection line 181 and the fourth conductive connection line 184 may not lie within the same axis (e.g., an axis extending in the X-direction may pass through the first conductive connection line 181 but not the fourth conductive connection line 184) and may not be collinear while being spaced apart in both the X-direction and the Y-direction. The conductive connection lines 180 may be connected to two bit lines 140 and bit line contacts BC, respectively. For example, as illustrated in FIG. 6, a memory cell region R1 may include first to third sub-cell regions SR1, SR2 and SR3 that are sequentially disposed in the X-direction. The bit lines 140 may include first to eighth bit lines 141, 142, 143, 144, 145, 146, 147 and 148. The conductive connection lines 180 may include first to fourth conductive connection lines 181, 182, 183 and 184.

The first bit line 141 may be disposed on the first sub-cell region SR1. The second bit line 142 and the third bit line 143 may be disposed on the second sub-cell region SR2. The second bit line 142 may be adjacent to the first bit line 141, and the third bit line 143 may be opposite to the second bit line 142 with respect to the center of the second sub-cell region SR2. As such, relative to the X-direction, the second bit line 142 may be between the first bit line 141 and the third bit line 143. The fourth bit line 144 may be disposed on the third sub-cell region SR3 and may be adjacent to the third bit line 143 such that, relative to the X-direction, the third bit line 143 may be between the second bit line 142 and the fourth bit line 144.

The first conductive connection line 181 may be connected to the first bit line 141 and the third bit line 143, and the second conductive connection line 182 may be connected to the second bit line 142 and the fourth bit line 144. The first conductive connection line 181 may be spaced apart from the second conductive connection line 182 in the Y-direction. The bit line contacts BC connected to the first conductive connection line 181 may be spaced apart from the bit line contacts BC connected to the second conductive connection line 182 in the Y-direction (see FIG. 8).

Referring further to FIG. 8, the fifth to eighth bit lines 145, 146, 147, 148 and the third to fourth conductive connection lines 183, 184 may have structures similar to the first to fourth bit lines 141, 142, 143, 144 and the first to second conductive connection lines 181, 182. For example, the fifth bit line 145 and the seventh bit line 147 may be connected to the third conductive connection line 183, and the sixth bit line 146 and the eighth bit line 148 may be connected to the fourth conductive connection line 184. The bit line contacts BC connected to the third conductive connection line 183 may be spaced apart from the bit line contacts BC connected to the fourth conductive connection line 184 in the Y-direction.

The cell array substrate CS of the semiconductor device 100 may further include upper interconnections 190, contacts C, and cell bonding pads BP1 on the stack structure SS and the pad structure PS. The upper interconnections 190 may be disposed at the same level as the second upper insulating layer 171 and may be in contact with word line contacts WC. The contacts C may be disposed at the same level as the third upper insulating layer 172, and the cell bonding pads BP1 may be disposed at the same level as the fourth upper insulating layer 173. The contacts C may connect the upper interconnections 190 and the cell bonding pads BP1. The contacts C may also connect conductive connection lines 180 to the cell bonding pads BP1. For example, each of the conductive connection lines 180 may be connected to one cell bonding pad BP1.

The peripheral circuit substrate PERI may include a peripheral substrate 201 and an element isolation region 203 defining an active region on the peripheral substrate 201. The peripheral substrate 201 may be, or include, a semiconductor substrate, for example, a crystalline semiconductor substrate and constitute an initial substrate (or base substrate) on which additional layers are formed (e.g., to form the peripheral circuit substrate PERI).

The peripheral circuits pTR may be disposed on the peripheral substrate 201. Each of the peripheral circuits pTR may include peripheral gate structures pGO and pGE disposed on the peripheral substrate 201, peripheral source/drain regions pSD disposed within the active region located on both sides of the peripheral gate structures pGO and pGE, and a peripheral channel region pCH between the peripheral source/drain regions pSD. The peripheral gate structures pGO and pGE may include a peripheral gate dielectric layer pGO and a peripheral gate electrode pGE that are sequentially stacked.

The peripheral circuit substrate PERI may further include an interconnection structure 220 disposed below the peripheral substrate 201 and electrically connected to the peripheral circuits pTR, peripheral bonding pads BP2 disposed below the interconnection structure 220, and an insulating structure 215. The insulating structure 215 may cover the peripheral substrate 201 and have a lower surface that is coplanar with lower surfaces of the peripheral bonding pads BP2. The lower surfaces of the peripheral bonding pads BP2 may be bonded to upper surfaces of the cell bonding pads BP1, and the lower surface of the insulating structure 215 may be bonded to an upper surface of the fourth upper insulating layer 173. As such, the peripheral circuit substrate PERI and the cell array substrate CS may be joined by a bonding method, for example, a hybrid bonding method, in which the lower surfaces of the peripheral bonding pads BP2 and the upper surfaces of the cell bonding pads BP1 are bonded and merged with each other, while the lower surface of the insulating structure 215 and the upper surface of the fourth upper insulating layer 173 are also bonded and merged with each other. Accordingly, the peripheral circuit substrate PERI may be bonded to the cell array substrate CS without adhesives or other intermediate joining materials provided between the peripheral circuit substrate PERI and the cell array substrate CS. The interconnection structure 220 may include interconnections extending in a horizontal direction and contacts that connect the interconnections with the peripheral circuits pTR and the peripheral bonding pads BP2.

In an example embodiment, the peripheral circuit substrate PERI may include bit line sense amplifiers, and the bit line sense amplifiers may include at least one peripheral circuit pTR. The bit line sense amplifiers may include bit line sense amplifiers SA1 and SA2 described with reference to FIG. 2. Each of the bit line sense amplifiers may be configured to be electrically connected to two global bit lines corresponding to different gate electrodes 120 (or, different pad portions 160). For example, as illustrated in FIG. 8, the first conductive connection line 181 may be connected to the same bit line sense amplifier as the third conductive connection line 183, and the second conductive connection line 182 may be connected to the same bit line sense amplifier as the fourth conductive connection line 184. For example, since eight bit lines are respectively connected to two bit line sense amplifiers, each bit line sense amplifier may occupy an area corresponding to four bit lines. For example, when the conductive connection lines 180 have an electrical connection relationship as illustrated in FIG. 2 and FIG. 8, each of the bit line sense amplifiers may have an area corresponding to the area illustrated in FIG. 6. For example, as illustrated in FIG. 6, one of the bit line sense amplifiers (e.g., the first bit line sense amplifier SA1, for example) may occupy the area indicated with dashed-lines in FIG. 6, such that the first bit line sense amplifier SA1 may have a length in the X-direction that is greater than a length (e.g., in the X-direction) of one of the sub-cell regions, such as the second sub-cell region SR2. In addition, the first bit line sense amplifier SA1 may have a width in the Y-direction that is greater than a combined width (e.g., in the Y-direction) of the first conductive connection line 181 and the second conductive connection line 182.

If the conductive connection lines 180 are not provided, the first bit line 141 is connected to the same bit line sense amplifier as the second bit line 142, and the third bit line 143 is connected to the same bit line sense amplifier as the fourth bit line 144. For example, compared to the case where the conductive connection lines 180 are not provided, the area in which a single bit line sense amplifier may be formed may be doubled according to example embodiments. Therefore, the size and spacing of the peripheral circuits pTR may be sufficiently large, so that the electrical characteristics of the peripheral circuits pTR may be improved. In addition, since the area where a single bit line sense amplifier may be formed increases, the size and spacing of the bonding pads BP1, BP2 may be increased, so that the bonding margin may be increased. According to example embodiments, a multiplexer (MUX) connecting a plurality of bit lines 140 is not formed, and a conductive connection line 180, which is a ‘global bit line’ connecting two bit lines 140, is formed, so that the semiconductor device 100 may be implemented more easily.

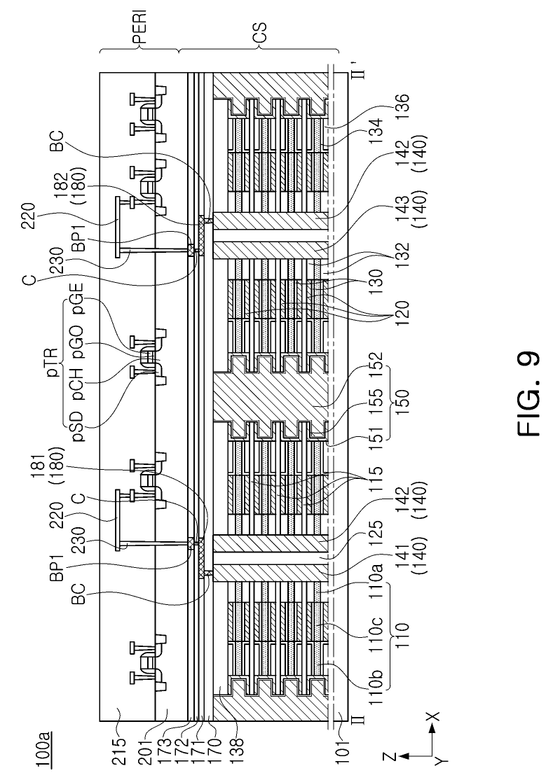

FIG. 9 is a vertical cross-sectional view of a semiconductor device according to an example embodiment.

Referring to FIG. 9, a semiconductor device 100a may include a cell array substrate CS and a peripheral circuit substrate PERI that is in contact with and bonded to the cell array substrate CS. Unlike the semiconductor device 100 of FIG. 7, the peripheral bonding pad BP2 may be omitted in the semiconductor device 100a of FIG. 9. For example, the peripheral circuit substrate PERI may include penetrating structures 230 that penetrate the peripheral substrate 201 and connect the interconnection structure 220 and the cell bonding pads BP1. The cell bonding pads BP1 and the fourth upper insulating layer 173 may be bonded to the peripheral circuit substrate PERI. According to an example embodiment, an insulating layer that contacts the cell bonding pads BP1 and the fourth upper insulating layer 173 may be disposed on the lower surface of the peripheral substrate 201.

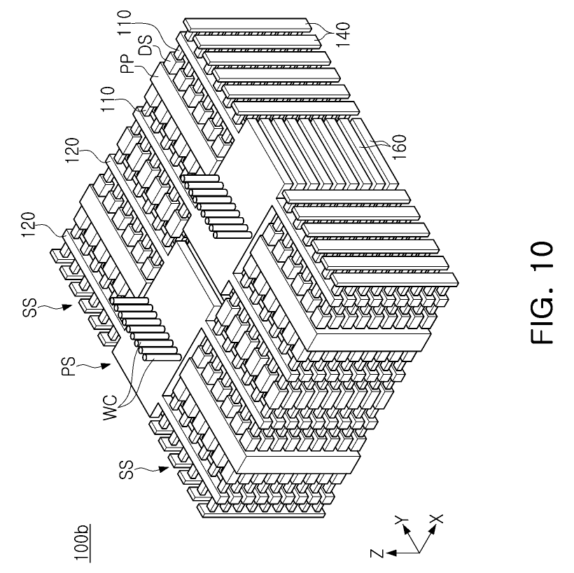

FIG. 10 is a schematic perspective view of a cell array substrate of a semiconductor device according to an example embodiment.

Referring to FIG. 10, the cell array substrate CS of a semiconductor device 100b may include stack structures SS including gate electrodes 120 and pad structures PS including pad portions 160. In an example embodiment, the horizontal widths of the pad portions 160 may be the same. For example, the areas of the vertically stacked pad portions 160 may be the same, and may not have a step structure. Each word line contact WC may vertically penetrate at least one pad portion 160 to be in contact with the upper surface of the corresponding pad portion 160. In an example embodiment, the pad structure PS may be disposed between the stack structures SS. For example, the first stack structure SS and the second stack structure SS may be spaced apart in the Y-direction with the pad structure PS therebetween, and the gate electrodes 120 of the first stack structure SS and the second stack structure SS may be in contact with the pad portions 160.

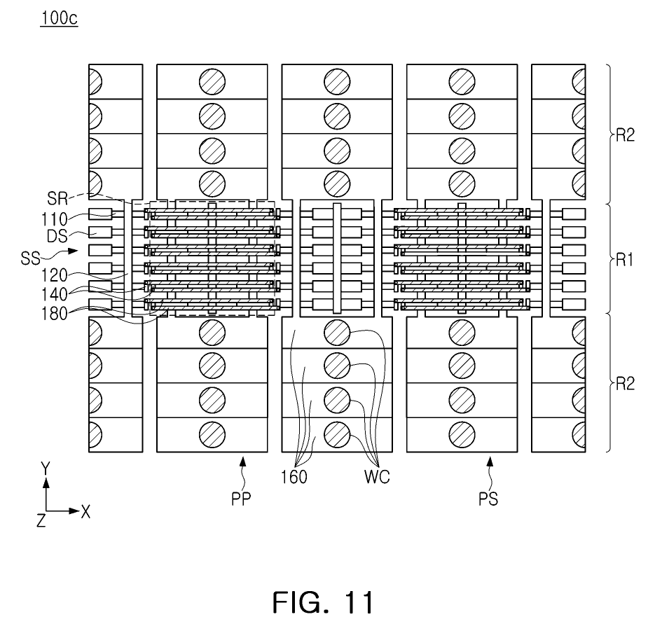

FIGS. 11 to 13 are plan views of cell array substrates of semiconductor devices according to example embodiments.

Referring to FIG. 11, the cell array substrate CS of a semiconductor device 100c may include stack structures SS disposed on a memory cell region R1 and pad structures PS disposed on a pad region R2. As described above, the stack structure SS may be disposed on a sub-cell region SR that overlaps the pad structure PS in the Y-direction.

In an example embodiment, the pad regions R2 may be spaced apart in the Y-direction with the memory cell region R1 interposed therebetween. For example, the pad structures PS may be spaced apart in the Y-direction with the stack structures SS interposed therebetween. Both ends of the gate electrodes 120 of the stack structures SS may be in contact with pad portions 160 of the pad structures PS that are spaced apart from each other in the Y-direction, respectively.

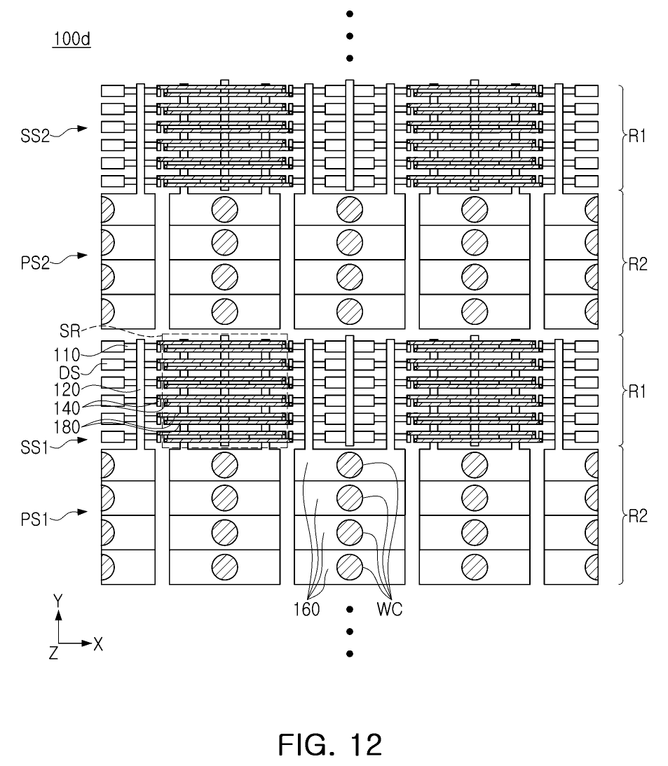

Referring to FIG. 12, the cell array substrate CS of a semiconductor device 100d may include stack structures SS disposed on a memory cell region R1 and pad structures PS disposed on a pad region R2. In an example embodiment, the memory cell regions R1 may be alternately disposed with the pad regions R2 along the Y-direction. For example, the stack structures SS may be alternately disposed with the pad structures PS along the Y-direction. For example, a first stack structure SS1, a first pad structure PS1, a second stack structure SS2, and a second pad structure PS2 may be alternately disposed in the Y-direction. The gate electrodes 120 of the first stack structure SS1 may be in contact with the pad portions 160 of the first pad structure PS1, and the gate electrodes 120 of the second stack structure SS2 may be in contact with the pad portions 160 of the second pad structure PS2. In an example embodiment, the directions in which the heights of the pad structures PS decrease may be the same and are similar to the description above relative to FIG. 5. For example, both the first pad structure PS1 and the second pad structure PS2 may decrease in height in the -Y-direction (the opposite direction to the direction indicated as the Y-direction).

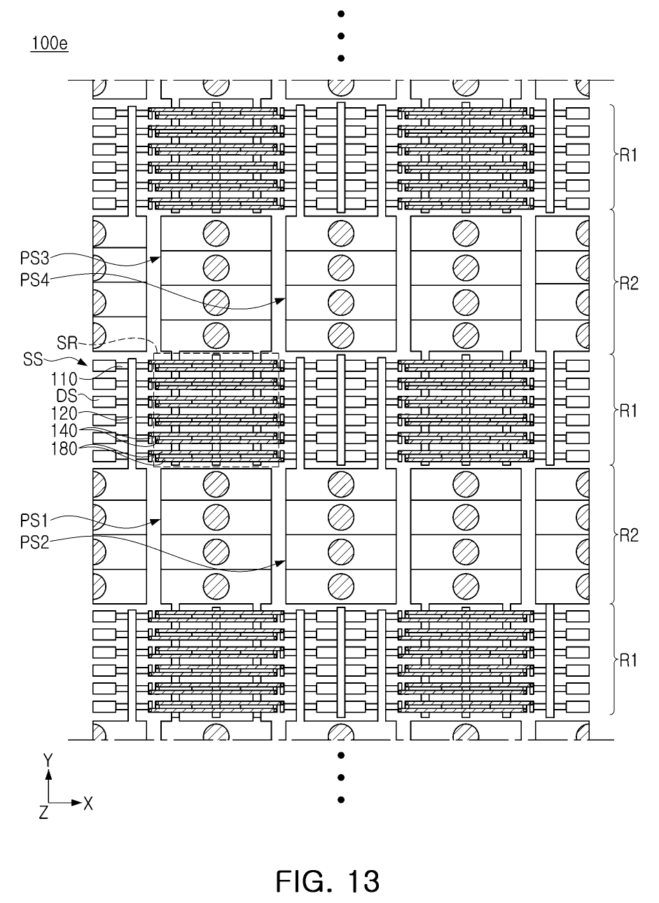

Referring to FIG. 13, the cell array substrate CS of a semiconductor device 100e may include stack structures SS disposed on a memory cell region R1 and pad structures PS disposed on a pad region R2. In an example embodiment, the memory cell regions R1 may be alternately disposed with the pad regions R2 along the Y-direction. In an example embodiment, the directions in which the heights of the pad structures PS decrease may be different from each other. For example, the pad structures PS may include a first pad structure PS1, a second pad structure PS2 adjacent to the first pad structure PS1 in the X-direction, a third pad structure PS3 adjacent to the first pad structure PS1 in the Y-direction, and a fourth pad structure PS4 adjacent to the third pad structure PS3 in the X-direction.

In an example embodiment, the directions in which the heights of the pad structures PS adjacent to each other in the X-direction decrease may be different from each other. For example, the first pad structure PS1 may decrease in height in the Y-direction, and the second pad structure PS2 may decrease in height in the -Y-direction. The third pad structure PS3 may decrease in height in the Y-direction, and the fourth pad structure PS4 may decrease in height in the -Y-direction. In an example embodiment, the directions in which the heights of the pad structures PS adjacent to each other in the Y-direction decrease may be different from each other. For example, the first pad structure PS1 and the third pad structure PS3 may have heights lowered in the -Y-direction, and the second pad structure PS2 and the fourth pad structure PS4 may have heights lowered in the Y-direction.

As set forth above, according to example embodiments, a conductive connection line may be disposed between bit lines and bit line sense amplifiers. The conductive connection line connects bit lines corresponding to different gate electrodes, and thus an area in which bit line sense amplifiers are formed may be increased. Therefore, the size of the bit line sense amplifiers may be increased, and electrical characteristics may be improved.

While example embodiments have been illustrated and described above, it will be apparent to those skilled in the art that modifications and variations could be made without departing from the scope of the present application.

What is claimed is:

1. A semiconductor device comprising:
a cell array substrate; and
a peripheral circuit substrate on the cell array substrate,
wherein the cell array substrate includes,
a memory cell region and a pad region adjacent to the memory cell region;
active patterns extending in a first horizontal direction on the memory cell region and spaced apart from each other in a vertical direction;
bit lines contacting the active patterns and extending in the vertical direction;
gate electrodes extending in a second horizontal direction that crosses the first horizontal direction, the gate electrodes intersecting the active patterns on the memory cell region;
conductive connection lines electrically connected to the bit lines, the conductive connection lines being on the memory cell region and extending in the first horizontal direction; and
pad portions connected to the gate electrodes and on the pad region,
wherein the memory cell region includes a first sub-cell region, a second sub-cell region and a third sub-cell region sequentially arranged in that order in the first horizontal direction,
the bit lines include,
a first bit line on the first sub-cell region;
a second bit line adjacent to the first bit line, on the second sub-cell region;
a third bit line spaced apart from the second bit line, on the second sub-cell region; and
a fourth bit line adjacent to the third bit line, on the third sub-cell region, and
the conductive connection lines include,
a first conductive connection line electrically connecting the first bit line and the third bit line, on the second sub-cell region; and
a second conductive connection line electrically connecting the second bit line and the fourth bit line, on the second sub-cell region.

2. The semiconductor device of claim 1, wherein each of the pad portions contacts two gate electrodes adjacent in the first horizontal direction among the gate electrodes.

3. The semiconductor device of claim 1, wherein the pad portions are spaced apart from each other in the vertical direction and are arranged in a step structure.

4. The semiconductor device of claim 1, further comprising a gate electrode contact penetrating at least one of the pad portions in the vertical direction,
wherein the pad portions have the same horizontal width in the first horizontal direction.

5. The semiconductor device of claim 1, wherein the first conductive connection line and the second conductive connection line extend in the first horizontal direction and are spaced apart from each other in the second horizontal direction.

6. The semiconductor device of claim 5, wherein the first conductive connection line is offset from the second conductive connection line in the first horizontal direction.

7. The semiconductor device of claim 1, further comprising:
first bit line contacts extending in the vertical direction on the first bit line and the third bit line, respectively, and contacting the first conductive connection line; and
second bit line contacts extending in the vertical direction on the second bit line and the fourth bit line, respectively, and contacting the second conductive connection line.

8. The semiconductor device of claim 7, wherein the first bit line contacts are spaced apart from the second bit line contacts in the first horizontal direction and the second horizontal direction.

9. The semiconductor device of claim 1, further comprising cell bonding pads disposed on the conductive connection lines and electrically connected to the conductive connection lines,
wherein the cell bonding pads are electrically connected to the peripheral circuit substrate.

10. The semiconductor device of claim 9, wherein the peripheral circuit substrate includes a first bit line sense amplifier disposed on a peripheral substrate and electrically connected to the first conductive connection line and a second bit line sense amplifier disposed on the peripheral substrate and electrically connected to the second conductive connection line.

11. The semiconductor device of claim 10,
wherein the peripheral circuit substrate further includes peripheral bonding pads electrically connected to the first and second bit line sense amplifiers and disposed on a lower surface of the peripheral circuit substrate, and
wherein the peripheral bonding pads are in contact with the cell bonding pads.

12. The semiconductor device of claim 10, wherein the peripheral circuit substrate further includes a penetrating structure vertically penetrating the peripheral substrate, contacting the cell bonding pads, and electrically connected to the first and second bit line sense amplifiers.

13. A semiconductor device comprising:
a cell array substrate; and
a peripheral circuit substrate on the cell array substrate,
wherein the cell array substrate includes,
a memory cell region and a pad region adjacent to the memory cell region;
stack structures arranged in a first horizontal direction on the memory cell region;
conductive connection lines extending in the first horizontal direction on the stack structures and spaced apart from each other in a second horizontal direction that crosses the first horizontal direction; and
pad structures connected to the stack structures and on the pad region,
each of the stack structures includes,
active patterns extending in the first horizontal direction;
bit lines extending in a vertical direction and contacting the active patterns; and
gate electrodes extending in the second horizontal direction and intersecting the active patterns, and
wherein the conductive connection lines are electrically connected to the bit lines and vertically overlap two adjacent gate electrodes among the gate electrodes.

14. The semiconductor device of claim 13, wherein the pad structures include pad portions spaced apart from each other in the vertical direction and connected to the gate electrodes.

15. The semiconductor device of claim 13, wherein the pad structures include first pad structures and second pad structures spaced apart in the second horizontal direction with the stack structures therebetween.

16. The semiconductor device of claim 15, wherein the gate electrodes contact pad portions of the first pad structures and the second pad structures, respectively.

17. The semiconductor device of claim 13, wherein the stack structures and the pad structures are alternately disposed in the second horizontal direction.

18. The semiconductor device of claim 17, wherein the pad structures have heights decreasing in the second horizontal direction.

19. The semiconductor device of claim 17,
wherein the pad structures include a first pad structure and a second pad structure adjacent in the first horizontal direction,
wherein the first pad structure decreases in height in the second horizontal direction, and
the second pad structure decreases in height in a third horizontal direction opposite to the second horizontal direction.

20. A semiconductor device comprising:
a cell array substrate; and
a peripheral circuit substrate on the cell array substrate,
wherein the cell array substrate includes,
a memory cell region and a pad region adjacent to the memory cell region;
stack structures arranged in a first horizontal direction on the memory cell region;
conductive connection lines extending in the first horizontal direction on the stack structures and spaced apart from each other in a second horizontal direction that crosses the first horizontal direction; and
pad structures connected to the stack structures and on the pad region,
each of the stack structures includes,
active patterns extending in the first horizontal direction;
bit lines extending in a vertical direction and contacting first side surfaces of the active patterns;
a data storage structure contacting second side surfaces of the active patterns, opposite to the first side surfaces; and
gate electrodes extending in the second horizontal direction, the gate electrodes surrounding the active patterns, and
wherein the pad structures include pad portions spaced apart from each other in the vertical direction and connected to the gate electrodes,
wherein the conductive connection lines are electrically connected to the bit lines and vertically overlap two adjacent gate electrodes among the gate electrodes, and
wherein ends of the conductive connection lines are disposed in a zigzag manner along the second horizontal direction.
